(19) United States
(12) Patent Application Publication
(10) Pub. No.: US 2005/0258533 A1
(43) Pub. Date: Nov. 24, 2005

(54) Semiconductor device mounting structure

(75) Inventors: Yutaka Kumano, Sanda-shi (JP); Tetsuyoshi Ogura, Settsu-shi (JP); Toru Yamada, Katano-shi (JP)

Correspondence Address: Hamre, Schumann, Mueller & Larson, P.C., P.O. Box 2902-0902, Minneapolis, MN, 55402, US

(73) Assignee: Matsushita Electric Industrial Co., Ltd., Kadoma-shi (JP)

(21) Appl. No.: 11/130,345

(22) Filed: May 16, 2005

(30) Foreign Application Priority Data
May 21, 2004 (JP) 2004-152314

(51) Int. Cl. H01L 23/34

(52) U.S. Cl. 257/712; 257/717

(57) ABSTRACT

A semiconductor device mounting structure is provided that includes an electrically insulating layer including a plurality of layers of electrically insulating substrates, a first semiconductor device, a second semiconductor device, a heat dispersion portion provided at a main surface of the electrically insulating layer, a first heat-conducting path connecting the heat dispersion portion and the first semiconductor device, and a second heat-conducting path connecting the heat dispersion portion and the second semiconductor device, wherein the first semiconductor device is arranged between at least a portion of the heat dispersion portion and the second semiconductor device. This provides a semiconductor device mounting structure that, in addition to being capable of high-density mounting of a plurality of semiconductor devices, is capable of dispersing with good efficiency heat generated by the plurality of semiconductor devices.

### BACKGROUND OF THE INVENTION

1. Field of the Invention

The present invention relates to semiconductor device mounting structures such as multilayer circuit boards and semiconductor packages on which semiconductor devices are mounted, and particularly relates to semiconductor device mounting structures on which a plurality of semiconductor devices are mounted.

2. Description of the Related Art

Typical mobile electronic devices such as mobile telephones, notebook computers, and digital cameras are undergoing rapid progress in being made smaller, thinner, and lighter. The demands for further advances in high performance and multi-functionality are also remarkable, and the miniaturization of semiconductor devices and circuit components required to meet these demands as well as the high density mounting technologies for these electronic components are progressing dramatically. Furthermore, along with developments in micro-processing technologies in recent years in the field of semiconductor devices, advances have been made in making higher density, larger scale semiconductor device mounting structures, and therefore the power consumption of semiconductor device mounting structures has increased greatly such that processes for heat dispersion for the large amount of heat produced by semiconductor devices have become an important issue.

As a conventional heat dispersion means for semiconductor device mounting structures, a means is known for dispersing the heat produced by semiconductor devices by attaching heat dispersion fins that are made of a highly thermally conductive metal on a surface of the semiconductor device mounting structure.

FIG. 6 shows a schematic cross-sectional view of a conventional semiconductor device mounting structure provided with the above-mentioned heat dispersion means. As shown in FIG. 6, a semiconductor device mounting structure 100 is provided with a substrate 101, a semiconductor device 102 arranged at an opening 101a of the substrate 101, and a heat sink 104 made of aluminum or the like provided via a thermal conductive adhesive 103 on the upper surface of the substrate 101 in the drawing. With this, heat produced by the semiconductor device 102 is conducted to the heat sink 104, and this heat is released into the air from a surface 104a of heat dispersion fins with which the heat sink 104 is provided. Furthermore, in the semiconductor device mounting structure 100, electrodes (not shown in drawings) provided at a circuit formation surface 102a of the semiconductor device 102 are connected to an external wiring 106b via gold wires 105, an internal wiring 106a, and a via conductor 107. Moreover, bumps 108 are formed that are connected to the external wiring 106b.

However, semiconductor device mounting structures provided with heat dispersion means based on such heat sinks require large mounting spaces and are difficult to apply for applications such as multi-chip packages (MCP) and system in package (SIP). In order to solve this problem, semiconductor device mounting structures have been disclosed that are provided with heat dispersion structures capable of being mounted on small electronic devices without using a heat sink (see JP H9-153679A, JP 2001-244638A, and JP 2000-12765A for example).

However, the semiconductor device mounting structures disclosed in JP H9-153679A and JP 2001-244638A are heat dispersion structures concerned with a single semiconductor device mounted in a package or on a circuit board and are insufficient for dispersing the large amounts of heat produced by a plurality of semiconductor devices mounted with high density on a surface or within an MCP or a multilayer circuit board and the like.

Furthermore, the semiconductor device mounting structure disclosed in JP 2000-12765A is a heat dispersion structure concerned with semiconductor devices mounted on a surface of a substrate and is insufficient for dispersing the heat produced by semiconductor devices accommodated within a multilayer circuit board or the like.

### SUMMARY OF THE INVENTION

The present invention solves these problems and provides a semiconductor device mounting structure that, in addition to being capable of high-density mounting of a plurality of semiconductor devices, is capable of dispersing with good efficiency heat generated by the plurality of semiconductor devices.

A semiconductor device mounting structure according to the present invention includes:

an electrically insulating layer including a plurality of layers of electrically insulating substrates;

a first semiconductor device arranged in the electrically insulating layer;

a second semiconductor device arranged in the electrically insulating layer or at a main surface of the electrically insulating layer;

a heat dispersion portion provided at a main surface of the electrically insulating layer;

a first heat-conducting path connecting the heat dispersion portion and the first semiconductor device; and

a second heat-conducting path connecting the heat dispersion portion and the second semiconductor device;

wherein the first semiconductor device is arranged between at least a portion of the heat dispersion portion and the second semiconductor device.

### BRIEF DESCRIPTION OF THE DRAWINGS

FIG. 1 is a schematic cross-sectional view of a semiconductor device mounting structure according to a first embodiment of the present invention.

FIG. 2 is a schematic cross-sectional view showing a modified example of a semiconductor device mounting structure according to the first embodiment of the present invention.

FIG. 3 is a schematic cross-sectional view of a semiconductor device mounting structure according to a second embodiment of the present invention.

FIG. 4 is a schematic cross-sectional view of a semiconductor device mounting structure according to a third embodiment of the present invention.

FIG. 5 is a schematic cross-sectional view of a semiconductor device mounting structure according to a fourth embodiment of the present invention.

FIG. 6 is a schematic cross-sectional view of a semiconductor device mounting structure provided with a conventional heat dispersion means.

### DESCRIPTION OF THE PREFERRED EMBODIMENTS

A semiconductor device mounting structure according to the present invention includes an electrically insulating layer including a plurality of layers of electrically insulating substrates, a first semiconductor device arranged in the electrically insulating layer, and a second semiconductor device arranged in the electrically insulating layer or at a main surface of the electrically insulating layer. There is no particular limitation on the electrically insulating substrates, but it is possible to use a material made of a composite material of a thermosetting resin and an inorganic filler for example. There is no particular limitation on the number of layers of electrically insulating substrates, and there may be two or more. Furthermore, the thicknesses of the electrically insulating substrates are in the range of 10 to 600 μm for example. Furthermore, the mounting of the first and second semiconductor devices can be achieved by commonly known methods and can be mounted using a flip chip joining technique for example (see JP 2002-261449A for example).

In addition to the above-described structure, a semiconductor device mounting structure according to the present invention includes a heat dispersion portion provided at a main surface of the electrically insulating layer, a first heat-conducting path connecting the heat dispersion portion and the first semiconductor device, and a second heat-conducting path connecting the heat dispersion portion and the second semiconductor device, wherein the first semiconductor device is arranged between at least a portion of the heat dispersion portion and the second semiconductor device. In this way, in addition to being able to achieve high density mounting of the first and second semiconductor devices, the heat produced by the first and second semiconductor devices can be dispersed with good efficiency from the heat dispersion portions via the first and second heat-conducting paths connected respectively to the first and second semiconductor devices.

A conductor pattern can be used for the heat dispersion portions, which are formed for example by performing patterning using a commonly known photolithographic technique on a metal foil such as a copper foil that has been arranged using a heat press or the like on a main surface of the electrically insulating layer. Furthermore, thermal vias can be used for the first and second heat-conducting paths, which are formed for example by forming through holes in desired positions on the electrically insulating substrate using a laser or the like and filling these through holes with a thermally conductive paste that includes a metal powder and a resin (for example, a thermosetting resin such as an epoxy resin), and then performing heat/pressure processing using a heat press or the like. Such thermal vias can be formed easily, and are therefore preferable as the first and second heat-conducting paths used in the present invention. It should be noted that the diameters of the above-mentioned through holes are approximately in the range of 100 to 500 μm for example. Furthermore, the first and second heat-conducting paths may be formed by performing a metal plating process inside the through holes for example instead of using the thermally conductive paste. Moreover, a combination of the conductor pattern and the thermal vias can be used for the first and second heat-conducting paths.

Furthermore, when the first and second semiconductor devices have different amounts of heat produced per unit volume (hereinafter “heat-generation density”), the semiconductor device mounting structure of the present invention further may include a bridging heat-conduction path that connects the first semiconductor device and the second semiconductor device. This is because the heat produced by the semiconductor device having a larger heat-generation density can be distributed via the bridging heat-conduction path to the semiconductor device having a smaller heat-generation density, and therefore the heat produced by the first and second semiconductor devices can be dispersed with very good efficiency. Furthermore, since the first and second semiconductor devices, which have different heat-generation densities, are connected by the bridging heat-conduction path in this structure, heat transfer occurs between the devices and the temperatures of the first and second semiconductor devices become balanced. In this way, the internal temperature of the semiconductor device mounting structure becomes uniform and the occurrence of thermal imbalances can be prevented, thus making it possible to improve the reliability of electrical connections in the semiconductor device mounting structure. It should be noted that the bridging heat-conduction path can be formed using the same method as the method for forming the above-described first and second heat-conducting paths. In particular, the above-mentioned thermal vias can be formed easily, and are therefore preferable as the bridging heat-conduction path used in the present invention.

Furthermore, in the semiconductor device mounting structure according to the present invention, at least of one the first and second semiconductor devices (hereinafter also referred to simply as “semiconductor devices”) may be flip chip mounted. This is because it is possible to make the semiconductor device mounting structure smaller and thinner by flip chip bonding the semiconductor devices and it is possible to meet the needs for smaller and thinner mobile electronic devices. Furthermore, the semiconductor devices and the heat-conducting paths (the first or the second heat-conducting path) may be connected by at least one of a heat-collecting pad, a heat-conducting bump, and a heat-collecting land. This is because the heat produced by the semiconductor devices can be dispersed with very good efficiency. Further still, a connection surface of at least one of the heat-collecting pad and the heat-collecting land may be formed in a concavo-convex shape. This is because the heat produced by the semiconductor devices can be dispersed with very good efficiency since the surface area of the connection surface can be enlarged. It should be noted that, when the heat-collecting pad, the heat-conducting bump, and the heat-collecting land are formed in this order between the semiconductor device and the heat-conducting path for example, the “connection surface” is the surface contacting the heat-conducting bump in the case of both the heat-collecting pad and the heat-collecting land. Furthermore, it is preferable that the height of the convex portions (or the depth of the concave portions) of the above-mentioned concavo-convex shape is in the range of 0.5 to 10 μm to enable greater enlargement of the surface area of the connection surface. Furthermore, ordinary pads, bumps, and lands can be used as the heat-collecting pads, heat-conducting bumps, and heat-collecting lands.

Furthermore, when the semiconductor device mounting structure of the present invention further includes the bridging heat-conduction path, the second semiconductor device may be flip chip mounted and the second semiconductor device and the bridging heat-conduction path may be connected via at least one of the heat-collecting pad, the heat-conducting bump, and the heat-collecting land. This is because the heat produced by the second semiconductor device can be dispersed with very good efficiency. Here too, a connection surface of at least one of the heat-collecting pad and the heat-collecting land may be formed in a concavo-convex shape. This is because the heat produced by the second semiconductor device can be dispersed with very good efficiency since the surface area of the connection surface can be enlarged. It should be noted that, as described above, ordinary pads, bumps, and lands can be used respectively as the heat-collecting pads, heat-conducting bumps, and heat-collecting lands.

Furthermore, the semiconductor device mounting structure according to the present invention may be a semiconductor device mounting structure in which the second semiconductor device has a larger surface area than the first semiconductor device and is arranged so as to cover the first semiconductor device with at least one of the electrically insulating substrates interposed therebetween. This is because the first semiconductor device, which has the smaller surface area, can be accommodated between the second semiconductor device, which has the larger surface area, and the heat dispersion portion, and therefore miniaturization of the semiconductor device mounting structure can be achieved easily. Furthermore, with this structure, the first and second heat-conducting paths can be formed passing through the electrically insulating substrates in the thickness direction, and therefore the lengths of the first and second heat-conducting paths can be shortened. In this way, the heat produced by the first and second semiconductor devices can be dispersed from the heat dispersion portions with even better efficiency. In this case, a semiconductor device (for example, a central processing unit (CPU)) having a computation function can be used as the first semiconductor device for example, and a semiconductor device (for example, a memory) having a storage function can be used as the second semiconductor device for example. The surface area of a semiconductor device having a computational function is typically approximately 1.0 cm², and the surface area of a semiconductor device having a storage function is typically approximately 3.0 cm², and therefore these suitably can be applied as the semiconductor devices used in the above-described structure. Hereinafter, embodiments of the present invention will be described with reference to the accompanying drawings.

### First Embodiment

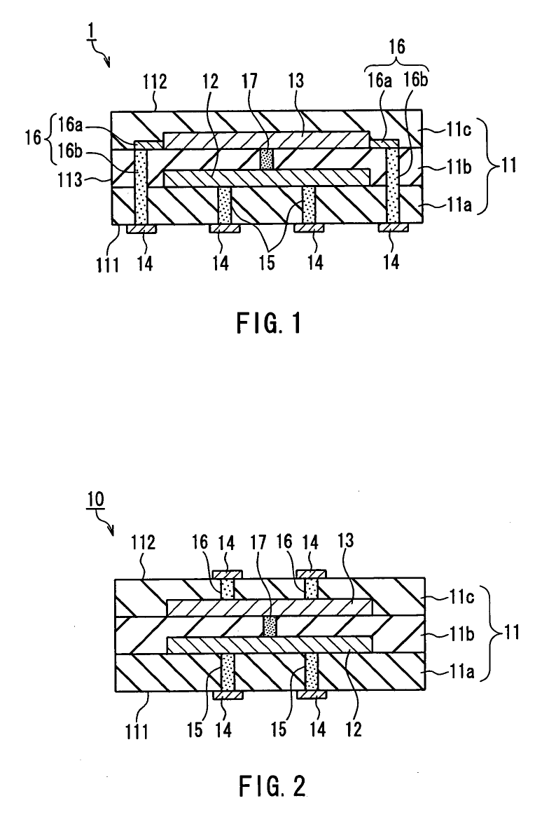

Firstly, a first embodiment of the present invention will be described with reference to the accompanying drawings as appropriate. FIG. 1 referenced here is a schematic cross-sectional view of a semiconductor device mounting structure according to a first embodiment of the present invention.

As shown in FIG. 1, a semiconductor device mounting structure 1 according to the first embodiment includes: an electrically insulating layer 11 that includes electrically insulating substrates 11a, 11b, and 11c; a first semiconductor device 12 arranged in the electrically insulating layer 11b; a second semiconductor device 13 arranged in the electrically insulating layer 11c; heat dispersion portions 14 provided on a main surface 111 on the electrically insulating layer 11a side of the electrically insulating layer 11; first heat-conducting paths 15 connected to the heat dispersion portions 14 and the first semiconductor device 12; second heat-conducting paths 16 connecting the heat dispersion portions 14 and the second semiconductor device 13; and a bridging heat-conduction path 17 connecting the first semiconductor device 12 and the second semiconductor device 13. Here, the first and second semiconductor devices 12 and 13 may have different heat-generation densities. Furthermore, the second heat-conducting paths 16 are constituted by conductor patterns 16a arranged within the electrically insulating substrate 11c and thermal vias 16b formed in the thickness direction of the electrically insulating substrates 11a and 11b. Furthermore, the first heat-conducting paths 15 are constituted by thermal vias formed in the thickness direction of the electrically insulating substrate 11a, and the bridging heat-conduction path 17 is constituted by a thermal via formed in the thickness direction of the electrically insulating substrate 11b. The first semiconductor device 12 is arranged between some of the heat dispersion portions 14 and the second semiconductor device 13. In this way, in addition to being able to achieve high density mounting of the first and second semiconductor devices 12 and 13, the heat produced by the first and second semiconductor devices 12 and 13 can be dispersed with good efficiency from the heat dispersion portions 14 via the first and second heat-conducting paths 15 and 16 connected respectively to the first and second semiconductor devices 12 and 13.

Furthermore, since the semiconductor device mounting structure 1 includes the bridging heat-conduction path 17, a heat flux caused by temperature differences between the first semiconductor device 12 and the second semiconductor device 13 is induced within the bridging heat-conduction path 17 such that heat is conducted from the semiconductor device having a larger heat-generation density to the semiconductor device having a smaller heat-generation density. In this way, the heat produced by the first and second semiconductor devices 12 and 13 can be dispersed with very good efficiency. Here, the semiconductor device that has the larger heat-generation density may be either of the first and second semiconductor devices 12 and 13.

The description above concerned a first embodiment of the present invention, but the present invention is not limited to the above-described embodiment. For example, in FIG. 1, the bridging heat-conduction path 17 is provided, but it is also possible that no bridging heat-conduction path is provided in the present invention. Furthermore, in FIG. 1, only a single layer of electrically insulating substrate is arranged between the first semiconductor device 12 and the second semiconductor device 13, but it is also possible that two or more layers of electrically insulating substrate are provided. Furthermore, it is also possible that the second semiconductor device 13 is mounted on a main surface 112 on the electrically insulating substrate 11c side of the electrically insulating layer 11. Furthermore, it is also possible to mount a further semiconductor device or devices (not shown in drawings) other than the first and second semiconductor devices 12 and 13. Furthermore, the numbers of first heat-conducting paths, second heat-conducting paths, bridging heat-conduction paths, and heat dispersion portions are not limited to the numbers shown in FIG. 1. Furthermore, the first and second heat-conducting paths 15 and 16 may have different cross sections. Furthermore, a second heat dispersion portion (not shown in drawings) further may be provided at a lateral surface 113 of the electrically insulating layer 11. Furthermore, as shown in FIG. 2, a semiconductor device mounting structure 10 is also possible in which the heat dispersion portions 14 are provided on the main surfaces 111 and 112 on both sides of the electrically insulating layer 11. In the structure shown in FIG. 2, the second heat-conducting paths 16 are constituted by thermal vias formed in the thickness direction of the electrically insulating substrate 11c. It should be noted that only the components necessary for describing the present invention are depicted in FIGS. 1 and 2, but ordinarily components such as via conductors and electrode terminals for transmitted electrical signals are provided in the electrically insulating layer 11. Of course, the first heat-conducting paths 15 and the second heat-conducting paths 16 may fulfill roles as via conductors that transmit electrical signals, and the heat dispersion portions 14 may fulfill roles as electrode terminals.

### Second Embodiment

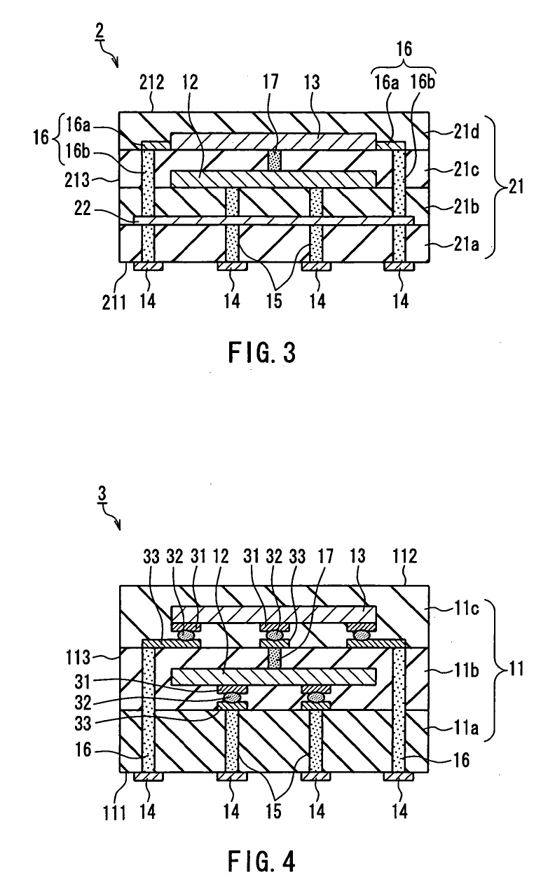

Next, a second embodiment of the present invention will be described with reference to the accompanying drawings as appropriate. FIG. 3 referenced here is a schematic cross-sectional view of a semiconductor device mounting structure according to a second embodiment of the present invention. It should be noted that in FIG. 3, members having the same structure as the semiconductor device mounting structure 1 according to the above-described first embodiment (see FIG. 1) will be given the same numerical symbol and the description thereof will be omitted.

As shown in FIG. 3, a semiconductor device mounting structure 2 according to the second embodiment includes an electrically insulating layer 21 that includes four layers of electrically insulating substrates 21a to 21d, and a shared heat-conducting path 22 provided in the electrically insulating substrate 21b, with the first and second heat-conducting paths 15 and 16 being connected to the shared heat-conducting path 22. The structure is otherwise the same as that of the above-described semiconductor device mounting structure 1 (see FIG. 1). In this way, the heat produced by the first and second semiconductor devices 12 and 13 can be dispersed with very good efficiency. It should be noted that the same method for forming the heat dispersion portions 14 can be used to as a method for forming the shared heat-conducting path 22. Furthermore, the shared heat-conducting path 22 may fulfill a role as a ground layer or a power source layer.

The description above concerned a second embodiment of the present invention, but the present invention is not limited to the above-described embodiment. For example, in FIG. 3, the bridging heat-conduction path 17 is provided, but it is also possible that no bridging heat-conduction path is provided in the present invention. Furthermore, in FIG. 3, only a single layer of electrically insulating substrate is arranged between the first semiconductor device 12 and the second semiconductor device 13, but it is also possible that two or more layers of electrically insulating substrate are provided. Furthermore, it is also possible that the second semiconductor device 13 is mounted on a main surface 212 on the electrically insulating substrate 21d side of the electrically insulating layer 21. Furthermore, it is also possible to mount a further semiconductor device or devices (not shown in drawings) other than the first and second semiconductor devices 12 and 13. Furthermore, the numbers of first heat-conducting paths, second heat-conducting paths, bridging heat-conduction paths, and heat dispersion portions are not limited to the numbers shown in FIG. 3. Furthermore, the first and second heat-conducting paths 15 and 16 may have different cross sections. Furthermore, the heat dispersion portions 14 may be provided on the main surfaces 211 and 212 on both sides of the electrically insulating layer 21. Furthermore, a second heat dispersion portion (not shown in drawings) may be further provided at a lateral surface 213 of the electrically insulating layer 21. It should be noted that only the components necessary for describing the present invention are depicted in FIG. 3, but ordinarily components such as via conductors and electrode terminals for transmitted electrical signals are provided in the electrically insulating layer 21. Of course, the first heat-conducting paths 15 and the second heat-conducting paths 16 may fulfill roles as via conductors that transmit electrical signals, and the heat dispersion portions 14 may fulfill roles as electrode terminals.

### Third Embodiment

Next, a third embodiment of the present invention will be described with reference to the accompanying drawings as appropriate. FIG. 4 referenced here is a schematic cross-sectional view of a semiconductor device mounting structure according to a third embodiment of the present invention. It should be noted that in FIG. 4, members having the same structure as the semiconductor device mounting structure 1 according to the above-described first embodiment (see FIG. 1) will be given the same numerical symbol and description thereof will be omitted.

As shown in FIG. 4, in a semiconductor device mounting structure 3 according to the third embodiment, the first and second semiconductor devices 12 and 13 are flip chip mounted. Furthermore, the second heat-conducting paths 16 are constituted by thermal vias formed in the thickness direction of the electrically insulating substrates 11a and 11b. Furthermore, in locations where the first semiconductor device 12 and the first heat-conducting paths 15 connect, heat-collecting pad 31, a heat-conducting bump 32, and a heat-collecting land 33 are arranged in this order from the first semiconductor device 12 side. Similarly, in locations where the second semiconductor device 13 and the second heat-conducting paths 16 connect, and in locations where the second semiconductor device 13 and bridging heat-conduction path 17 connect, a heat-collecting pad 31, a heat-conducting bump 32, and a heat-collecting land 33 are arranged in this order from the second semiconductor device 13 side. The structure is otherwise the same as the above-described semiconductor device mounting structure 1 (see FIG. 1). In this way, since heat can be conducted efficiently from the first and second semiconductor devices 12 and 13 to the respective first and second heat-conducting paths 15 and 16, the heat produced by the first and second semiconductor devices 12 and 13 can be dispersed with very good efficiency.

The description above concerned a third embodiment of the present invention, but the present invention is not limited to the above-described embodiment. For example, in FIG. 4, the bridging heat-conduction path 17 is provided, but it is also possible that no bridging heat-conduction path is provided in the present invention. Furthermore, there is no particular limitation to the number of layers of electrically insulating substrate arranged between the first semiconductor device 12 and the second semiconductor device 13. Furthermore, it is also possible that the second semiconductor device 13 is mounted on a main surface 112 on the electrically insulating substrate 11c side of the electrically insulating layer 11. Furthermore, it is also possible to mount a further semiconductor device or devices (not shown in drawings) other than the first and second semiconductor devices 12 and 13. Furthermore, the numbers of first heat-conducting paths, second heat-conducting paths, bridging heat-conduction paths, and heat dispersion portions are not limited to the numbers shown in FIG. 4. Furthermore, the first and second heat-conducting paths 15 and 16 may have different cross sections. Furthermore, the heat dispersion portions 14 may be provided on the main surfaces 111 and 112 on both sides of the electrically insulating layer 11. Furthermore, a second heat dispersion portion (not shown in drawings) further may be provided at a lateral surface 113 of the electrically insulating layer 11. It should be noted that only the components necessary for describing the present invention are depicted in FIG. 4, but ordinarily components such as via conductors and electrode terminals for transmitted electrical signals are provided in the electrically insulating layer 11. Of course, the first heat-conducting paths 15 and the second heat-conducting paths 16 may fulfill roles as via conductors that transmit electrical signals, and the heat dispersion portions 14 may fulfill roles as electrode terminals.

### Fourth Embodiment

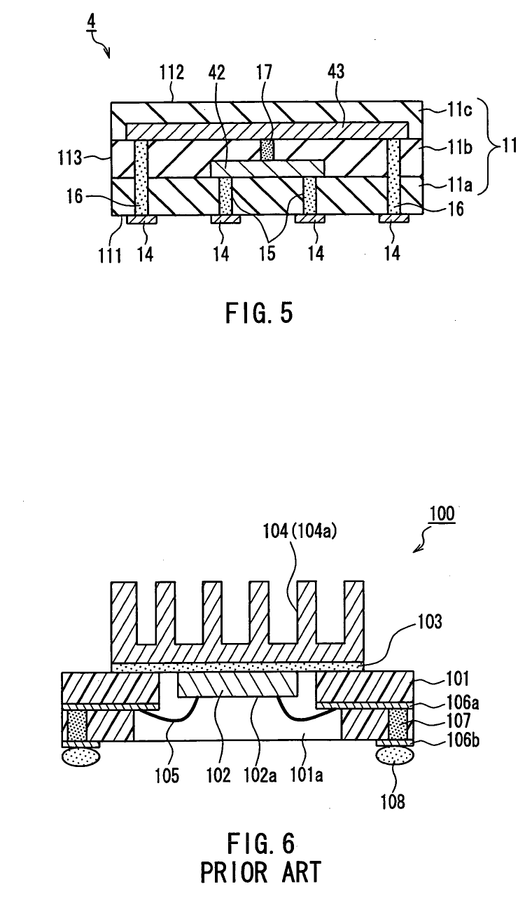

Next, a fourth embodiment of the present invention will be described with reference to the accompanying drawings as appropriate. FIG. 5 referenced here is a schematic cross-sectional view of a semiconductor device mounting structure according to a fourth embodiment of the present invention. It should be noted that in FIG. 5, members having the same structure as the semiconductor device mounting structure 1 according to the above-described first embodiment (see FIG. 1) will be given the same numerical symbol and description thereof will be omitted.

As shown in FIG. 5, in a semiconductor device mounting structure 4 according to the fourth embodiment, a second semiconductor device 43 is arranged so as to cover a first semiconductor device 42 via the electrically insulating substrate 11b. Furthermore, compared to the first semiconductor device 42, the second semiconductor device 43 has a larger surface area and a smaller heat-generation density. For example, a semiconductor device having a computation function such as a central processing unit (CPU) can be used as the first semiconductor device 42, and a semiconductor device having a storage function such as a memory can be used as the second semiconductor device 43. Furthermore, the second heat-conducting paths 16 are constituted by thermal vias formed in the thickness direction of the electrically insulating substrates 11a and 11b. The structure is otherwise the same as the above-described semiconductor device mounting structure 1 (see FIG. 1). In this way, in addition to being able to accommodate the first semiconductor device 42, which has the smaller surface area, between the second semiconductor device 43, which has the larger surface area, and the heat dispersion portions 14, the heat produced by the first and second semiconductor devices 42 and 43 can be dispersed with good efficiency from the heat dispersion portions 14 via the first and second heat-conducting paths 15 and 16 connected respectively to the first and second semiconductor devices 42 and 43. Accordingly, in addition to high heat dispersibility, it is possible to provide a semiconductor device mounting structure by which miniaturization can be achieved easily.

The description above concerned a fourth embodiment of the present invention, but the present invention is not limited to the above-described embodiment. For example, in FIG. 5, the bridging heat-conduction path 17 is provided, but it is also possible that no bridging heat-conduction path is provided in the present invention. Furthermore, in FIG. 5, only a single layer of electrically insulating substrate is arranged between the first semiconductor device 42 and the second semiconductor device 43, but it is also possible that two or more layers of electrically insulating substrate are arranged. Furthermore, it is also possible that the second semiconductor device 43 is mounted on a main surface 112 on the electrically insulating substrate 11c side of the electrically insulating layer 11. Furthermore, it is also possible to mount a further semiconductor device or devices (not shown in drawings) other than the first and second semiconductor devices 42 and 43. Furthermore, the numbers of first heat-conducting paths, second heat-conducting paths, bridging heat-conduction paths, and heat dispersion portions are not limited to the numbers shown in FIG. 5. Furthermore, the first and second heat-conducting paths 15 and 16 may have different cross sections. Furthermore, the heat dispersion portions 14 may be provided on the main surfaces 111 and 112 on both sides of the electrically insulating layer 11. Furthermore, a second heat dispersion portion (not shown in drawings) further may be provided at a lateral surface 113 of the electrically insulating layer 11. It should be noted that only the components necessary for describing the present invention are depicted in FIG. 5, but ordinarily components such as via conductors and electrode terminals for transmitted electrical signals are provided in the electrically insulating layer 11. Of course, the first heat-conducting paths 15 and the second heat-conducting paths 16 may fulfill roles as via conductors that transmit electrical signals, and the heat dispersion portions 14 may fulfill roles as electrode terminals.

As described above, with a semiconductor device mounting structure according to the present invention, in addition to being able to achieve high-density mounting of a plurality of semiconductor devices, it is possible to disperse with good efficiency the heat generated by the plurality of semiconductor devices, and therefore miniaturization of semiconductor device mounting structures such as MCP and multilayer circuit boards are easily achievable. Accordingly, the present invention can be suitably used for electronic devices in which demands are being made for smaller and thinner devices, such as mobile telephones.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A semiconductor device mounting structure comprising:
an electrically insulating layer including a plurality of layers of electrically insulating substrates;
a first semiconductor device arranged in the electrically insulating layer;
a second semiconductor device arranged in the electrically insulating layer or at a main surface of the electrically insulating layer;
a heat dispersion portion provided at a main surface of the electrically insulating layer;
a first heat-conducting path connecting the heat dispersion portion and the first semiconductor device; and
a second heat-conducting path connecting the heat dispersion portion and the second semiconductor device;
wherein the first semiconductor device is arranged between at least a portion of the heat dispersion portion and the second semiconductor device.

2. The semiconductor device mounting structure according to claim 1, wherein at least one of the first and second semiconductor devices is flip chip mounted.

3. The semiconductor device mounting structure according to claim 1, wherein the first and second semiconductor devices have different amounts of heat produced per unit volume, and
wherein the semiconductor device mounting structure further comprises a bridging heat-conduction path that connects the first semiconductor device and the second semiconductor device.

4. The semiconductor device mounting structure according to claim 3, wherein at least one of the first and second semiconductor devices is flip chip mounted.

5. The semiconductor device mounting structure according to claim 1, wherein the first semiconductor device is flip chip mounted, and
wherein the first semiconductor device and the first heat-conducting path are connected via at least one of a heat-collecting pad, a heat-conducting bump, and a heat-collecting land.

6. The semiconductor device mounting structure according to claim 5, wherein a connection surface of at least one of the heat-collecting pad and the heat-collecting land is formed in a concavo-convex shape.

7. The semiconductor device mounting structure according to claim 1, wherein the second semiconductor device is flip chip mounted, and
wherein the second semiconductor device and the second heat-conducting path are connected via at least one of a heat-collecting pad, a heat-conducting bump, and a heat-collecting land.

8. The semiconductor device mounting structure according to claim 7, wherein a connection surface of at least one of the heat-collecting pad and the heat-collecting land is formed in a concavo-convex shape.

9. The semiconductor device mounting structure according to claim 3, wherein the second semiconductor device is flip chip mounted, and
wherein the second semiconductor device and the bridging heat-conduction path are connected via at least one of a heat-collecting pad, a heat-conducting bump, and a heat-collecting land.

10. The semiconductor device mounting structure according to claim 9, wherein a connection surface of at least one of the heat-collecting pad and the heat-collecting land is formed in a concavo-convex shape.

11. The semiconductor device mounting structure according to claim 1, wherein the second semiconductor device has a larger surface area than the first semiconductor device and is arranged so as to cover the first semiconductor device with at least one of the electrically insulating substrates interposed therebetween.

12. The semiconductor device mounting structure according to claim 11, wherein the first semiconductor device is a semiconductor device having a computational function, and
wherein the second semiconductor device is a semiconductor device having a storage function.

13. The semiconductor device mounting structure according to claim 1, wherein at least one of the first and second heat-conducting paths includes a portion formed from a thermally conductive paste that includes a metal powder and a resin.

14. The semiconductor device mounting structure according to claim 3, wherein at least a portion of the bridging heat-conduction path is formed from a thermally conductive paste that includes a metal powder and a resin.
